(19) United States
(12) Patent Application Publication
(10) Pub. No.: US 2026/0043141 A1
(43) Pub. Date: Feb. 12, 2026

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Yuji TAKEBAYASHI, Toyama-shi (JP); Takefumi MORI, Toyama-shi (JP); Yuya MIYANISHI, Toyama-shi (JP)

(73) Assignee: KOKUSAI ELECTRIC CORPORATION, Tokyo (JP)

(21) Appl. No.: 19/337,127

(22) Filed: Sep. 23, 2025

Related U.S. Application Data
(63) Continuation of application No. PCT/JP2023/013245, filed on Mar. 30, 2023.

(51) Int. Cl. C23C 16/52; C23C 16/455

(52) U.S. Cl. CPC C23C 16/52; C23C 16/45561

(57) ABSTRACT

There is provided a technique that includes a storage configured to store a process gas supplied from a supplier, a processing chamber configured to process a substrate, a plurality of gas flow paths that connect the storage and the processing chamber in parallel, a gas control mechanism including a plurality of valves respectively disposed in the plurality of gas flow paths, and a controller configured to be capable of controlling the gas control mechanism so as to perform a process including: (a1) storing the process gas in the storage; (a2) starting supply of the process gas in the storage into the processing chamber; (a3) stopping supply of the process gas in the storage into the processing chamber; and (b) changing conductance of gas in the gas flow paths by controlling opening degrees of the valves between the processing of (a2) and the processing of (a3).

### CROSS-REFERENCE TO RELATED APPLICATION

This application is a Bypass Continuation application of PCT International Application No. PCT/JP2023/013245, filed on Mar. 30, 2023, the entire contents of which are incorporated herein by reference.

### BACKGROUND

### Field

The present disclosure relates to a substrate processing apparatus, a method of processing a substrate, a method of manufacturing a semiconductor device and a recording medium.

### Description of the Related Art

Conventionally, a semiconductor manufacturing apparatus for manufacturing a semiconductor device is known as an example of a substrate processing apparatus. In addition, as an example of a semiconductor manufacturing apparatus, a substrate processing apparatus that stores a process gas in a storage, then supplies the process gas to a substrate in a processing chamber, and processes the substrate is known.

### SUMMARY

Along with miniaturization of devices, it is required to process a groove having a high aspect ratio with good step coverage.

The present disclosure provides a technique capable of processing a groove having a high aspect ratio with good step coverage.

According to one aspect of the present disclosure, there is provided a technology including a storage configured to store a process gas supplied from a supplier, a processing chamber configured to process a substrate, a plurality of gas flow paths that connect the storage and the processing chamber in parallel, a gas control mechanism including a plurality of valves respectively disposed in the plurality of gas flow paths, and a controller configured to be capable of controlling the gas control mechanism so as to perform a process including: (a1) storing the process gas in the storage; (a2) starting supply of the process gas in the storage into the processing chamber; (a3) stopping supply of the process gas in the storage into the processing chamber; and (b) changing a conductance of gas in the gas flow paths by controlling opening degrees of the valves between (a2) and (a3).

### BRIEF DESCRIPTION OF THE DRAWINGS

FIG. 1 is a longitudinal sectional view showing a schematic configuration of a vertical processing furnace of a substrate processing apparatus suitably used in one aspect of the present disclosure.

FIG. 2 is a schematic transverse sectional view taken along line A-A in FIG. 1.

FIG. 3 is a schematic configuration diagram of a controller of the substrate processing apparatus suitably used in one aspect of the present disclosure, and is a block diagram illustrating a control system of the controller.

FIG. 4 is a schematic diagram showing a part of the substrate processing apparatus suitably used in one aspect of the present disclosure.

FIG. 5 is a flowchart of a source gas supply process in a substrate processing process suitably used in one aspect of the present disclosure.

FIG. 6 is a diagram schematically illustrating a pressure of a gas in a processing chamber, a flow rate of the gas, a flow velocity of the gas, and opening/closing timing of a valve in the substrate processing process suitably used in one aspect of the present disclosure.

FIG. 7 is a schematic configuration diagram of a controller of a substrate processing apparatus suitably used in another aspect of the present disclosure, and is a block diagram illustrating a control system of the controller.

FIG. 8 is a diagram showing a pressure of a gas in a processing chamber, a flow rate of the gas, a flow velocity of the gas, and opening/closing timing of a valve in a substrate processing process suitably used in another aspect of the present disclosure.

FIG. 9 is a schematic configuration diagram of a controller of a substrate processing apparatus suitably used in another aspect of the present disclosure, and is a block diagram illustrating a control system of the controller.

### DETAILED DESCRIPTION

### First Embodiment

### (Configuration)

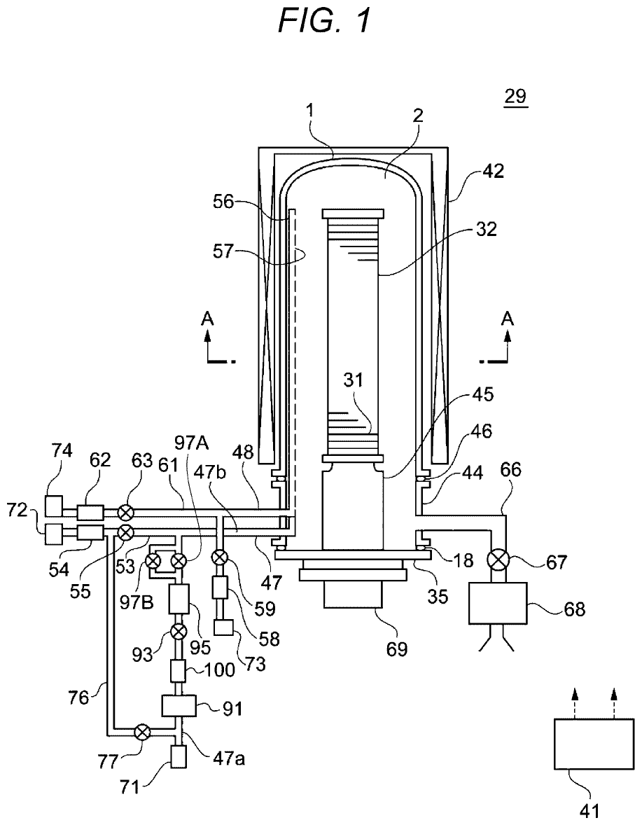

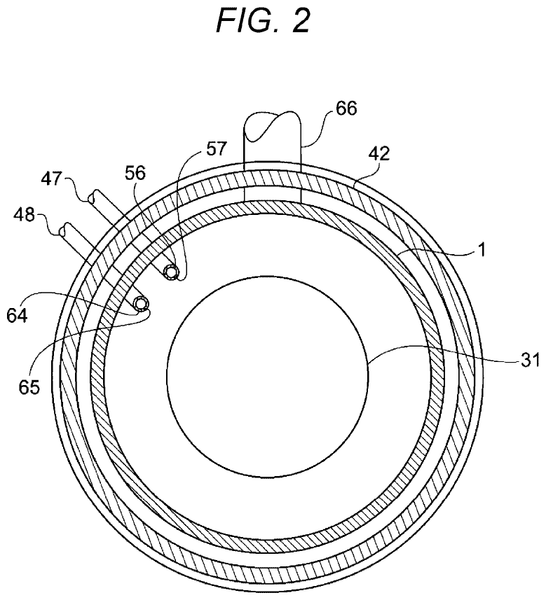

FIG. 1 and FIG. 2 illustrate a substrate processing apparatus 29 which is an example of a processing apparatus in which the present disclosure is implemented. The drawings used in the following description are all schematic, and dimensional relationships of respective elements, ratios of respective elements, and the like illustrated in the drawings do not necessarily coincide with actual ones. In addition, dimensional relationships of the respective elements, ratios of the respective elements, and the like do not necessarily coincide among the plurality of drawings.

The substrate processing apparatus 29 will be described using FIG. 1 and FIG. 2. A reaction tube 1 is provided inside a heater 42 as a heating device (heating means), and a temperature sensor (not illustrated) serving as a temperature detector is installed in the reaction tube 1. A manifold 44, made of stainless steel or the like, for example, is continuously provided at the lower end of the reaction tube 1 via an O-ring 46 which is an airtight member. A lower end opening portion (furnace opening portion) of the manifold 44 is airtightly closed by a seal cap 35 which is a lid body via an O-ring 18 which is an airtight member, and a processing chamber 2 is defined by at least the reaction tube 1, the manifold 44, and the seal cap 35.

A boat 32 is erected on the seal cap 35 via a boat support base 45, and the boat support base 45 serves as a holding body that holds the boat 32. As a result, as illustrated in FIG. 1, a plurality of wafers 31 is accommodated in the processing chamber 2, and substrate processing which will be described later is performed. The number of wafers 31 is, for example, 2 to 200, preferably 5 to 150, and more preferably 25 to 100. A boat rotation mechanism 69 is provided on the seal cap 35. The boat rotation mechanism 69 can rotate the boat 32 in the processing chamber 2.

The notation of a numerical range such as “2 to 200” in the present specification means that a lower limit value and an upper limit value are included in the range. Therefore, for example, “2 to 200” means “2 or more and 200 or less”. The same applies to other numerical ranges.

Two gas supply pipes (a first gas supply pipe 47 and a second gas supply pipe 48) serving as supply paths for supplying a plurality of types, here, two types of process gases, are provided to the processing chamber 2.

The first gas supply pipe 47 is provided with, in order from the upstream, a raw material unit 71, a vaporizer 91, and a first mass flow controller (hereinafter, also referred to as MFC) 100 that is a liquid flow rate control device (flow rate control means). The vaporizer 91 is an example of a supplier of the present disclosure. On the downstream side of the first MFC 100 of the first gas supply pipe 47, a storage amount adjustment valve 93 which is an on-off valve, a tank 95, a first flow rate adjustment valve 97A, and a first nozzle 56 disposed in the processing chamber 2 are provided in this order from the upstream. A flow path provided with a second flow rate adjustment valve 97B connects between the tank 95 and the storage amount adjustment valve 93 and connects between the first flow rate adjustment valve 97A and the first nozzle 56. In other words, the tank 95 and the processing chamber 2 are connected in parallel by a plurality of gas flow paths. In the present embodiment, among respective gas flow paths, the gas flow path provided with the first flow rate adjustment valve 97A is referred to as a first flow path 96A, and the gas flow path provided with the second flow rate adjustment valve 97B is referred to as a second flow path 96B. Both the first flow path 96A and the second flow path 96B may be a part of the first gas supply pipe 47.

In the description of the present embodiment, when the first flow rate adjustment valve 97A and the second flow rate adjustment valve 97B are not distinguished from each other, one or both of the first flow rate adjustment valve 97A and the second flow rate adjustment valve 97B are referred to as a flow rate adjustment valve 97. In the description of the present embodiment, when first flow path 96A and second flow path 96B are not distinguished from each other, one or both of first flow path 96A and second flow path 96B are referred to as a gas flow path 96.

A first carrier gas supply pipe 53 for supplying a carrier gas is connected to the downstream side of the first flow rate adjustment valve 97A and the second flow rate adjustment valve 97B. The first carrier gas supply pipe 53 is provided with a carrier gas source 72, a second MFC 54, and a valve 55 that is an on-off valve in this order from the upstream. In addition, a first nozzle 56 is provided at a distal end portion of the first gas supply pipe 47 from a lower portion to an upper portion along the inner wall of the reaction tube 1, and first gas supply holes 57 for supplying gas are provided on a side surface of the first nozzle 56. The first gas supply holes 57 are provided at equal pitches from the lower portion to the upper portion, and have the same opening area. An inert gas (for example, N₂ gas) as a carrier gas is supplied from the carrier gas source 72 to the first carrier gas supply pipe 53. In addition, a supply pipe 76 that connects the first carrier gas supply pipe and the first carrier gas supply pipe 53 is provided such that an inert gas can be supplied upstream of the first MFC 100. Here, flow of the inert gas in the supply pipe 76 is controlled by the valve 77.

Here, the first gas supply pipe 47, the first MFC 100, the storage amount adjustment valve 93, the tank 95, the first flow rate adjustment valve 97A, and the second flow rate adjustment valve 97B are collectively referred to as a first gas supplier (first gas supply line). The vaporizer 91 and/or the first nozzle 56 may be included in the first gas supplier. The first carrier gas supply pipe 53, the second MFC 54, and the valve 55 may be included in the first gas supplier. Furthermore, the raw material unit 71 and the carrier gas source 72 may be included in the first gas supplier.

The second gas supply pipe 48 is provided with a reaction gas source 73, a third MFC 58, and a valve 59 that is an on-off valve in order from the upstream direction, and a second carrier gas supply pipe 61 for supplying a carrier gas is joined to the downstream side of the valve 59. The second carrier gas supply pipe 61 is provided with a carrier gas source 74, a fourth MFC 62, and a valve 63 that is an on-off valve in this order from the upstream. A second nozzle 64 is provided at a distal end portion of the second gas supply pipe 48 in parallel with the first nozzle 56, and second gas supply holes 65 which are supply holes for supplying gas are provided on a side surface of the second nozzle 64. The second gas supply holes 65 are provided at equal pitches from the lower portion to the upper portion, and have the same opening area.

Here, the second gas supply pipe 48, the third MFC 58, the valve 59, and the second nozzle 64 are collectively referred to as a second gas supplier (second gas supply line). The second carrier gas supply pipe 61, the fourth MFC 62, and the valve 63 may be included in the second gas supplier. Furthermore, the reaction gas source 73 and the carrier gas source 74 may be included in the second gas supplier.

A liquid raw material supplied from the raw material unit 71 is vaporized in the vaporizer 91 to become a source gas. From the vaporizer 91, the source gas joins the first carrier gas supply pipe 53 via the first MFC 100, the storage amount adjustment valve 93, the tank 95, the first flow rate adjustment valve 97A, and the second flow rate adjustment valve 97B, and is further supplied into the processing chamber 2 via the first nozzle 56. A reaction gas supplied from the reaction gas source 73 joins the second carrier gas supply pipe 61 via the third MFC 58 and the valve 59, and is further supplied to the processing chamber 2 via the second nozzle 64.

The supply pipe 76 and the valve 77 are used when the source gas is purged from the first gas supplier.

The processing chamber 2 is connected to a gas exhaust pipe 66 for exhausting gas. The gas exhaust pipe 66 is provided with a pressure sensor (not illustrated), an auto pressure controller (APC) valve 67 serving as a pressure regulator, and a vacuum pump 68 serving as a vacuum exhaust device in order from the upstream. The vacuum pump 68 is configured to perform vacuum exhaust such that the pressure in the processing chamber 2 becomes a predetermined pressure (degree of vacuum). A controller 41 is electrically connected to the APC valve 67 and the pressure sensor. The controller 41 is configured to control the opening degree of the APC valve 67 based on the pressure detected by the pressure sensor such that the pressure in the processing chamber 2 becomes a desired pressure at a desired timing. An exhaust unit (exhaust system) mainly includes the gas exhaust pipe 66, the pressure sensor, and the APC valve 67. The vacuum pump 68 may be included in the exhaust unit.

The vaporizer 91 heats and vaporizes a raw material supplied as a liquid to generate a source gas, and supplies the source gas to the tank 95. As the raw material, for example, a chlorosilane-based gas such as a monochlorosilane (SiH₃Cl) gas, a dichlorosilane (SiH₂Cl₂) gas, a trichlorosilane (SiHC₁₃) gas, a tetrachlorosilane (SiCl₄) gas, a hexachlorodisilane gas (Si₂Cl₆) gas, or an octachlorotrisilane (Si₃Cl₈) gas can be used. As the source gas, for example, a fluorosilane-based gas such as a tetrafluorosilane (SiF₄) gas and a difluorosilane (SiH₂F₂) gas, a bromosilane-based gas such as a tetrabromosilane (SiBr₄) gas and a dibromosilane (SiH₂Br₂) gas, or an iodosilane-based gas such as a tetraiodosilane (SiI₄) gas and a diiodosilane (SiH₂I₂) gas can also be used. Further, as the source gas, for example, an aminosilane-based gas such as tetrakis (dimethylamino) silane (Si[N(CH₃)₂]₄) gas, tris(dimethylamino) silane (Si[N(CH₃)₂]₃H) gas, bis(diethylamino) silane (Si[N(C₂H₅)₂]2H₂) gas, or bis(tertiary butylamino) silane (SiH₂[NH(C₄H₉)]₂) gas can also be used. As the source gas, for example, an organic silane source gas such as tetraethoxysilane (Si(OC₂H₅)₄) gas can also be used. One or more of these gases can be used as the source gas. That is, raw materials stored as liquid by pressurization or cooling can also be included. In the present embodiment, a case in which the vaporizer 91 supplies only the source gas to the tank 95 without supplying the carrier gas will be described as an example.

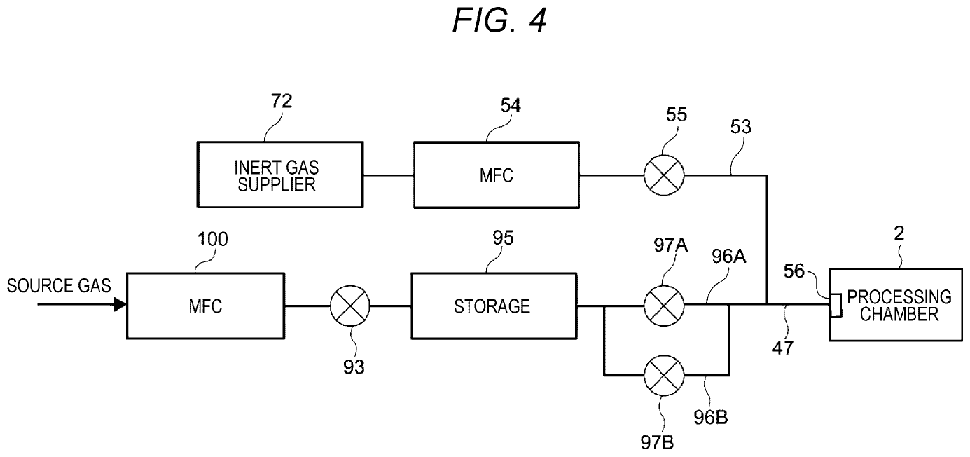

Next, each configuration of the first gas supply line according to the present embodiment will be described with reference to FIG. 4. FIG. 4 is an enlarged view of the periphery of the first gas supply pipe 47.

The tank 95 stores the source gas supplied from the vaporizer 91. In the present disclosure, the number of tanks is not limited to one, and can be arbitrarily set including two or more tanks. The tank 95 is an example of a storage in the present disclosure.

The tank 95 and the processing chamber 2 are connected in parallel by the first flow path 96A and the second flow path 96B. The first flow rate adjustment valve 97A is provided on the first flow path 96A, and the second flow rate adjustment valve 97B is provided on the second flow path 96B. Here, the first flow rate adjustment valve 97A and the second flow rate adjustment valve 97B are an example of a gas control mechanism including a plurality of valves disposed in a plurality of flow paths connecting the storage and the processing chamber in parallel in the present disclosure. The first flow rate adjustment valve 97A and the second flow rate adjustment valve 97B are examples of a first valve and a second valve in the present disclosure.

In the present embodiment, the first flow rate adjustment valve 97A and the second flow rate adjustment valve 97B may have different conductances indicating ease of gas flow.

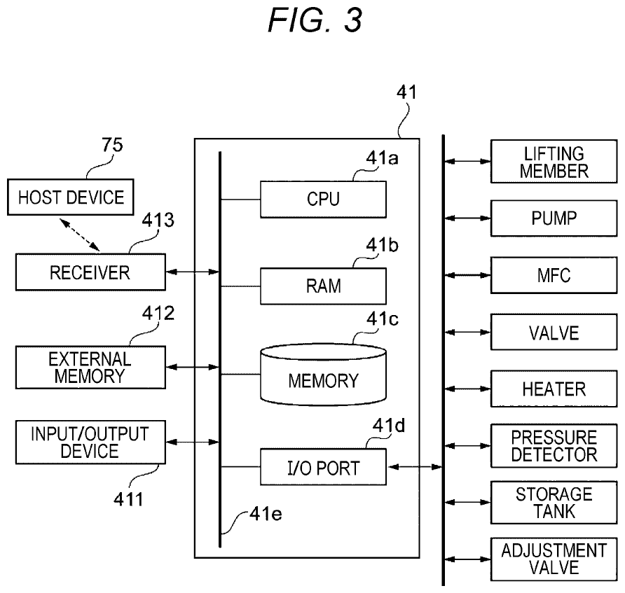

An outline of the controller 41 is illustrated in FIG. 3. The controller 41 that is a controller (control means) is configured as a computer including a central processing unit (CPU) 41a, a random access memory (RAM) 41b, a memory 41c, and an I/O port 41d. The RAM 41b, the memory 41c, and the I/O port 41d are configured to be able to exchange data with the CPU41a via an internal bus 41e. An input/output device 411 configured as, for example, a touch panel or the like and an external memory 412 are configured to be connectable to the controller 41. Furthermore, a receiver 413 connected to a host device 75 via a network is provided. The receiver 413 can receive information of another device from the host device 75.

The memory 41c includes, for example, a flash memory, a hard disk drive (HDD), or the like. In the memory 41c, a control program for controlling the operation of the substrate processing apparatus, a process recipe in which procedures, conditions, and the like of substrate processing which will be described later are described, a correction recipe, and the like are readably stored. The process recipe and the correction recipe are combined such that the controller 41 can execute each procedure in a substrate processing process and a characteristic confirmation process performed in a substrate processing mode to obtain a predetermined result, and function as a program. In the present specification, the term “program” is used in a case including only a process recipe or a correction recipe, a case including only a control program alone, or a case including both of the cases. In addition, the RAM 41b is configured as a memory area (work area) in which a program, data, and the like read by the CPU 41a are temporarily stored.

The I/O port 41d is connected to a boat elevator, the heater 42, the temperature sensor, the boat rotation mechanism 69, the vaporizer 91, the first MFC 100, the storage amount adjustment valve 93, the first flow rate adjustment valve 97A, the second flow rate adjustment valve 97B, the carrier gas source 72, the second MFC 54, the valve 77, the reaction gas source 73, the third MFC 58, the valve 59, the carrier gas source 74, the fourth MFC 62, the valve 63, the APC valve 67, the vacuum pump 68, and the like.

The CPU 41a reads a control program from the memory, executes the control program, and reads the process recipe from the memory 41c in response to an input of an operation command from the input/output device 411, or the like. The CPU 41a is configured to control the operation of adjusting flow rates of various gases by the first MFC 100, the second MFC 54, the third MFC 58, and the fourth MFC 62, operations of the storage amount adjustment valve 93, the first flow rate adjustment valve 97A, the second flow rate adjustment valve 97B, the valve 77, the valve 59, and the valve 63, the operation of the APC valve 67 and the operation of adjusting the pressure in the processing chamber 2 by the APC valve 67 based on the pressure sensor, the output adjustment operation of the heater 42 based on the temperature sensor, the start and stop of the vacuum pump 68, the rotation and rotation speed adjustment operation of the boat 32 by the boat rotation mechanism 69, the operation of raising and lowering the boat 32 by the boat elevator, and the like according to the contents of the read process recipe.

The controller 41 is not limited to being configured as a dedicated computer, and may be configured as a general-purpose computer. For example, the controller 41 according to the present embodiment can be configured by preparing the external memory (for example, a semiconductor memory such as a USB memory or a memory card, and the like) 412 storing the above-described program and installing the program in a general-purpose computer using the external memory 412. The means for supplying the program to the computer is not limited to the case of supplying the program via the external memory 412. For example, the program may be supplied using a communication means such as the Internet or a dedicated line instead of the external memory 412. The memory 41c and the external memory 412 are configured as computer-readable recording media. Hereinafter, these are collectively referred to simply as a recording medium. In the present specification, the term “recording medium” may be used in a case including only the memory 41c alone, a case including only the external memory 412 alone, or a case including both.

### <Method of Manufacturing Semiconductor Device and Method of Processing Substrate>

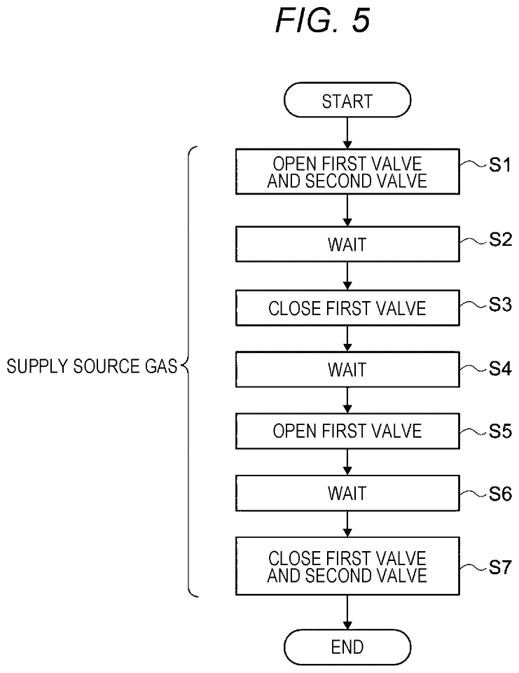

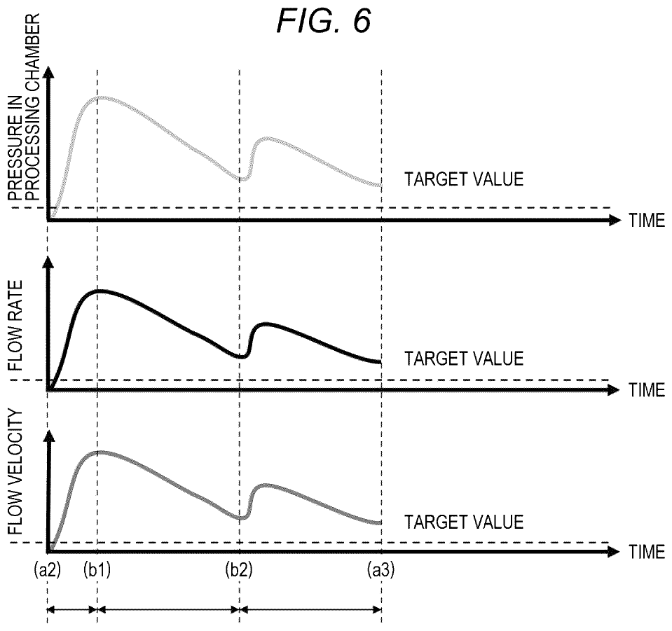

Next, an example of a method of manufacturing a semiconductor device and a method of processing a substrate will be described with reference to FIG. 1, FIG. 4, FIG. 5, FIG. 6, and Table 1. Here, as an example of a semiconductor device manufacturing process, film forming processing of alternately supplying a source (source gas) as one of process gases and a reactant (reaction gas) as one of process gases to the processing chamber will be described. In the present embodiment, an example in which a silicon nitride film (Si₃N₄ film, hereinafter also referred to as SiN film) is formed on a substrate using a Si source gas as an example of a source and a nitrogen-containing gas as a reactant will be described. In the following description, the operation of each portion constituting the substrate processing apparatus 29 is controlled by the controller 41.

First, as described above, the wafers 31 are loaded into the boat 32 and loaded into the processing chamber 2. After the boat 32 is loaded into the processing chamber 2, the pressure and temperature in the processing chamber 2 are adjusted. Next, film forming processing is executed.

In the film forming processing in the present embodiment, a SiN film is formed on the wafer 31 by performing a predetermined number of times (one or more times) of a cycle of non-simultaneously performing a process of supplying a source gas to the wafer 31 in the processing chamber 2 (film forming process 1), a purge process of removing the source gas (residual gas) from the processing chamber 2 (film forming process 2), a process of supplying a nitrogen-containing gas to the wafer 31 in the processing chamber 2 (film forming process 3), and a purge process of removing the nitrogen-containing gas (residual gas) from the processing chamber 2 (film forming process 4).

### (Film Forming Process 1)

In the film forming process 1, a layer containing an element derived from the source gas is formed on the surface of the wafer 31 by an operation of storing the source gas supplied from the vaporizer 91 in the tank 95 and then supplying the source gas to the wafer 31 in the processing chamber 2 (hereinafter referred to as flash supply). In the present embodiment, since the Si source gas is used as the source gas, a Si-containing layer is formed.

Here, the film forming process 1 includes (a1) processing of storing the source gas in the tank 95 and a process of supplying the source gas in the tank 95 into the processing chamber 2 (source gas supply process). In addition, the source gas supply process includes (a2) processing of starting supply of the source gas in the tank into the processing chamber 2, (a3) processing of stopping supply of the process gas in the tank into the processing chamber 2, and (b) processing of changing the conductance of the gas in the gas flow path 96 by controlling the gas control mechanism between the processing of (a2) and the processing of (a3). In (b), the gas control mechanism changes the gas flow path 96 by controlling the opening degree of the flow rate adjustment valve 97. Here, controlling the opening degree of the flow rate adjustment valve 97 in (b) means controlling opening and closing of the valve and/or the opening degree of the flow rate adjustment valve 97 while continuing supply of the process gas in the tank 95 into the processing chamber 2. In the present embodiment, the valve 67 is opened, and film forming processing is performed while the source gas is discharged from the processing chamber.

In the film forming process 1, the source gas and the carrier gas may be merged and flowed in the first gas supply pipe 47. Specifically, when the source gas is supplied from the tank 95 to the processing chamber 2 between (a2) and (a3), the valve 55 may be opened to cause the carrier gas whose flow rate has been adjusted by the second MFC 54 to flow from the first carrier gas supply pipe 53 to the first gas supply pipe 47, and cause the source gas and the carrier gas to merge in the first gas supply pipe 47 and then flow into the processing chamber 2. Hereinafter, an example of a case in which only the source gas is supplied to the processing chamber 2 without supplying the carrier gas in the film forming process 1 will be described.

In (a1), the controller 41 performs processing of supplying the source gas vaporized in the vaporizer 91 to the tank 95 and storing the source gas in the tank 95 by the first MFC 100. For example, by opening the storage amount adjustment valve 93 in a state in which the first flow rate adjustment valve 97A and the second flow rate adjustment valve 97B are closed, the source gas vaporized in the vaporizer 91 is supplied to the tank 95. That is, the controller 41 executes (a1) processing of storing the process gas in the storage in the present disclosure. In this state, high-pressure source gas is stored in the tank 95.

Next, details of the source gas supply process will be described with reference to FIG. 5, FIG. 6, and Table 1. Table 1 shows opening and closing of the first valve (first flow rate adjustment valve 97A) and the second valve (second flow rate adjustment valve 97B) and change in gas conductance in the gas flow path 96 in the source gas supply process of the present embodiment.

TABLE 1

| Processing | (a2) | . . . | (b1) | . . . | (b2) | . . . | (a3) |
|---|---|---|---|---|---|---|---|
| First valve | Open | Open | Close | Close | Open | Open | Close |
| Second valve | Open | Open | Open | Open | Open | Open | Close |
| Conductance CV | A + B | A + B | B | B | A + B | A + B | 0 |

In Table 1, “Open” indicates that the first flow rate adjustment valve 97A or the second flow rate adjustment valve 97B is in an open state, and “Close” indicates that the first flow rate adjustment valve 97A or the second flow rate adjustment valve 97B is in a closed state. With respect to the conductance in Table 1, “A” indicates the conductance of the first flow rate adjustment valve 97A, and “B” indicates the conductance value of the second flow rate adjustment valve 97B. Here, the value A and the value B are set to satisfy a relationship of A>B.

After the processing of (a1), the controller 41 supplies the source gas in the tank 95 to the processing chamber 2 via the first flow path 96A and the second flow path 96B by opening both the first flow rate adjustment valve 97A and the second flow rate adjustment valve 97B (step S1 in FIG. 5). That is, the controller 41 executes the processing of (a2) in the present disclosure.

Subsequently, the controller 41 executes processing of waiting for a first time that is a predetermined time (step S2 in FIG. 5). For example, the controller 41 waits in a range of 0.05 seconds to 2.00 seconds.

At this time, as illustrated in FIG. 6, the pressure inside the processing chamber 2, the flow rate of the source gas, and the flow velocity of the source gas rapidly increase. The “flow rate” in FIG. 6 represents the flow rate of the raw material supplied to the inside of the processing chamber 2 per unit time, and the “flow velocity” in FIG. 6 represents the average flow velocity of the source gas flowing through the surface of the wafer 31.

Here, as a comparative example of the present embodiment, processing of supplying a predetermined gas A to a wafer will be considered. In such processing, a byproduct generated by reaction of the gas A is adsorbed to the wafer, and thus adsorption of the gas A to the wafer may be inhibited. In such a case, the step coverage can be improved by increasing the amount of the gas A adsorbed to the wafer before the amount of the byproduct adsorbed to the wafer increases.

In the present embodiment, the source gas stored in the tank 95 in the processing of (a1) is supplied into the processing chamber 2 in the processing of (a2). As a result, after the processing of (a2) is performed, the flow velocity of the source gas supplied to the wafer 31, the pressure in the processing chamber 2, and/or the flow rate of the source gas supplied into the processing chamber 2 per unit time can be increased. In such a state, the amount of the source gas adsorbed to the wafer can be increased before the amount of the byproduct adsorbed to the wafer 31 increases, and thus the step coverage can be improved.

Subsequently, the controller 41 executes processing of closing the first flow rate adjustment valve 97A (step S3 in FIG. 5). At this time, since the source gas inside the tank 95 is supplied to the processing chamber 2 through the second flow path 96B, the conductance of the gas flow path 96 decreases as compared with that after the processing of (a2). That is, the controller 41 executes (b1) processing of decreasing the conductance in the gas flow path 96 in the present disclosure. In other words, the controller 41 decreases the conductance of the gas flow path 96. Here, the process of (b1) is an example of the processing of (b) in the present disclosure.

Subsequently, the controller 41 executes processing of waiting until a second time that is a predetermined time elapses from (b1) (step S4 in FIG. 5). More specifically, the controller 41 waits in a range of 0.05 seconds to 2.00 seconds.

As the amount of the source gas adsorbed to the wafer 31 increases with the elapse of time from the start of the supply of the source gas, the byproduct is less likely to be adsorbed to the wafer 31. From this, it can be said that the influence of decrease in the step coverage due to the byproduct decreases as time elapses from the processing of (a2). In such a case, even if the flow velocity of the source gas supplied to the wafer 31, the pressure in the processing chamber 2, and/or the flow rate of the source gas supplied to the processing chamber 2 per unit time decrease, the step coverage is less likely to decrease.

In the present embodiment, the amount of the source gas supplied from the tank 95 per unit time can be reduced after an elapse of time from the processing of (a2) and the influence of the byproduct on decrease in the step coverage is reduced. This makes it possible to improve the step coverage while reducing the amount of the source gas consumed in substrate processing. Therefore, an increase in the cost of substrate processing can be suppressed.

Subsequently, the controller 41 executes processing of opening the first flow rate adjustment valve 97A (step S5 in FIG. 5). At this time, since the source gas in the tank 95 is supplied to the processing chamber 2 through the first flow path 96A and the second flow path 96B, the conductance in the gas flow path 96 is increased as compared with that after the processing of (b1). That is, the controller 41 executes (b2) processing of increasing the conductance in the gas flow path 96 in the present disclosure. In other words, the controller 41 increases the conductance of the gas flow path 96. In the present embodiment, as illustrated in FIG. 6, the processing of (b2) is performed such that the pressure of the source gas, the flow rate of the source gas, and the flow velocity of the source gas in the processing chamber 2 increase. Here, the processing of (b2) is an example of the processing of (b) in the present disclosure.

Subsequently, the controller 41 executes processing of waiting for a predetermined time (step S6 in FIG. 5). More specifically, the controller 41 waits in a range of 0.05 seconds to 2.00 seconds.

When the conductance of the gas flow path 96 is increased by the processing of (b2), the amount of the source gas supplied from the tank 95 per unit time can be increased. As a result, as compared with the case in which the processing of (b2) is not performed, it is possible to lengthen the time during which the flow velocity of the source process gas supplied to the substrates of the wafer 31, the pressure in the processing chamber 2 (or the partial pressure of the process gas in the processing chamber 2), and/or the flow rate of the source process gas supplied to the processing chamber 2 per unit time are high. Here, as the flow velocity of the source process gas supplied to the substrate of the wafer 31 increases, it is possible to suppress a decrease in step coverage due to thermal decomposition of the source gas. In addition, as the pressure (or the partial pressure of the process gas in the processing chamber 2) in the processing chamber 2 increases, the source gas can easily reach a deep portion side of a recess having a high aspect ratio. In addition, as the flow rate of the source process gas supplied into the processing chamber 2 per unit time increases, the flow velocity of the source process gas supplied to the substrate of the wafer 31 and the pressure in the processing chamber 2 are easily increased. Therefore, step coverage is easily improved.

Subsequently, the controller 41 executes processing of closing the first flow rate adjustment valve 97A and the second flow rate adjustment valve 97B (step S7 in FIG. 5). That is, the controller 41 executes (a3) processing of stopping the supply of the process gas in the tank 95 into the processing chamber 2 in the present disclosure.

Here, the first time is preferably set such that a predetermined parameter is equal to or greater than a target value between the processing of (a2) and the processing of (b1). Similarly, the second time is preferably set such that the predetermined parameter is equal to or greater than the target value between the processing of (b1) and the processing of (b2). Here, the predetermined parameter is, for example, at least one or more of the flow velocity of the source gas supplied to the wafer 31, the pressure of the gas in the processing chamber 2, and the flow rate of the source gas supplied to the processing chamber 2 per unit time. In this manner, by setting the first time and/or the second time, it is possible to further increase the time during which the predetermined parameter is equal to or greater than the target value. Therefore, step coverage is more likely to be improved.

### (Film Forming Process 2)

In the film forming process 2, the inside of the processing chamber 2 is evacuated by the vacuum pump 68 by opening the valve 67 (vacuum exhaust). As a result, the gas remaining in the processing chamber 2 can be removed after the film forming process 1. At this time, when the valve 55 and/or the valve 63 is opened to supply N₂ gas to the processing chamber 2 (inert gas purge), it is possible to further enhance the effect of removing the remaining source gas.

### (Film Forming Process 3)

In the film forming process 3, a nitrogen-containing gas and a carrier gas are caused to flow. Specifically, the valve 59 provided in the second gas supply pipe 48 and the valve 63 provided in the second carrier gas supply pipe 61 are both opened. As a result, the nitrogen-containing gas whose flow rate has been adjusted by the third MFC 58 and the carrier gas whose flow rate has been adjusted by the third MFC 62 are mixed in the second gas supply pipe 48, and are exhausted from the gas exhaust pipe 66 while being supplied from the second gas supply hole 65 of the second nozzle 64 into the processing chamber 2. By supplying the nitrogen-containing gas, a Si-containing layer on the wafer 31 and the nitrogen-containing gas react with each other, and an SiN film is formed on the wafer 31.

### (Film Forming Process 4)

In the film forming process 4, for example, vacuum exhaust or inert gas purge is performed through the same procedure as the film forming process 2. As a result, the gas remaining in the processing chamber 2 can be removed after the film forming process 3.

With the film forming processes 1 to 4 described above as one cycle, this cycle is performed a predetermined number of times (one or more times). As a result, a SiN film having a predetermined thickness can be formed on the wafer 31.

After the above-described cycle is performed a predetermined number of times, an inert gas such as N₂ gas is supplied into the processing chamber 2 and exhausted (inert gas purge). Thereafter, the atmosphere in the processing chamber 2 is replaced with an inert gas (inert gas replacement), and the pressure in the processing chamber 2 is returned to normal pressure (atmospheric pressure). Then, the wafer 31 (substrate) is unloaded from the processing chamber 2.

Next, operations and effects according to the present embodiment will be described.

### (Operations and Effects)

According to the present embodiment, one or a plurality of effects described below can be further obtained in addition to the effects described above.

(1) In the present embodiment, the processing of (b) of changing the conductance of the gas flow path 96 is performed by controlling the gas control mechanism provided in each of a plurality of gas flow paths connecting the tank 95 and the processing chamber 2 in parallel and including a plurality of valves. As a result, the conductance of the gas flow path 96 can be changed in a wide range in the processing of (b), and thus the conductance of the gas flow path 96 can be greatly increased and/or decreased in the processing of (b1) and the processing of (b2). This makes it easier to obtain the effects of the processing of (b1) and the processing of (b2).

(2) In the present embodiment, the gas flow path 96 between the tank 95 and the processing chamber 2 branches into the first flow path 96A and the second flow path 96B on the downstream side of the tank 95, and the first flow rate adjustment valve 97A and the second flow rate adjustment valve 97B serving as a gas control mechanism are disposed in parallel in the branched flow paths, and the processing of (b) is performed by controlling the valves of the gas flow paths 96. As a result, it is possible to provide a plurality of flow paths that connect the tank 95 and the processing chamber 2 in parallel while minimizing the number of branches of the gas flow path 96, and thus, it is possible to suppress an increase in the footprint of the substrate processing apparatus.

(3) In the present embodiment, the processing of (b1) and the processing of (b2) are performed in the processing of (b). As a result, both the effect according to the processing of (b1) and the effect according to the processing of (b2) can be obtained.

(4) In the present embodiment, in the processing of (b), since the processing of (b2) is performed after the processing of (b1), the conductance of the gas flow path 96 can be increased by the processing of (b2) after the conductance of the gas flow path 96 is decreased by the processing of (b1). As change in the conductance of the gas flow path 96 due to the processing of (b2) increases, the amount of the process gas supplied from the tank 95 per unit time increases. Therefore, the time during which the parameter related to the improvement of the step coverage by the processing of (b2) can continue to be high is likely to increase.

(5) When more wafers 31 are processed in the processing chamber 2, the volume of the processing chamber 2 and the total surface areas of the wafers 31 increase, and thus the amount of the process gas supplied per unit time also tends to increase. Then, as the supply amount of the process gas increases, in order to sufficiently obtain the above-described effects in such a case, it is preferable that change in the conductance of the gas flow path 96 in the processing of (b) be also large. As described above, in the present embodiment, the minimum conductance of the gas flow path 96 can be made smaller than the maximum conductance. Therefore, according to the configuration of the present embodiment, the above-described effects can be sufficiently obtained even in a case in which a plurality of wafers 31 is simultaneously processed.

(6) In the processing of (b1) and the processing of (b2), as change in the conductance per unit time increases, the time between switching between a high conductance state and a low conductance state can be decreased. The on-off valve can change conductance more rapidly than an opening degree adjusting valve whose opening can be adjusted. Therefore, by performing the processing of (b) such that at least one of opening and closing of one or more of the on-off valves are included using at least one of the plurality of valves serving as the gas control mechanism as the on-off valve, the above-described effects can be sufficiently obtained. In addition, when all the plurality of valves serving as the gas control mechanism are the on-off valves, the above-described effects can be more sufficiently obtained.

(7) In the present embodiment, in (b), the conductance is changed by processing including opening and closing of an on-off valve having the largest conductance among the plurality of valves. As a result, the conductance of the gas flow path 96 can be largely switched in a short time, and thus the effects as described above can be more sufficiently obtained.

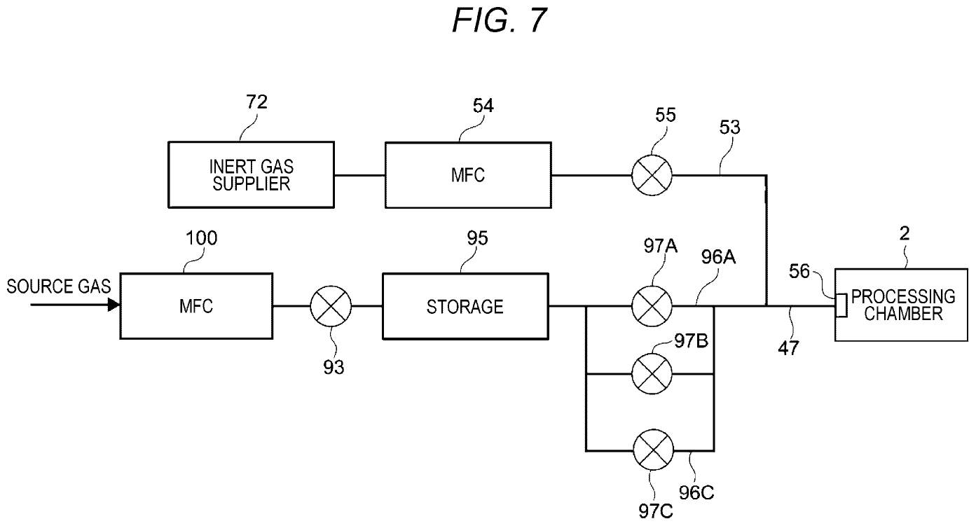

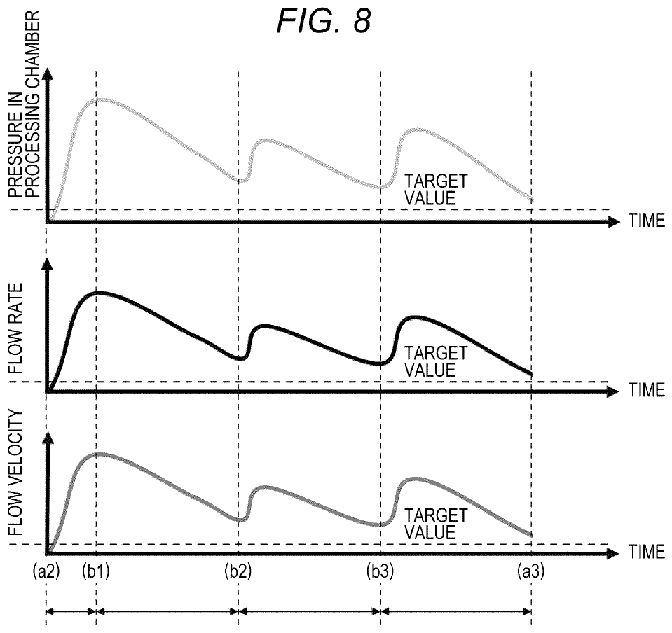

Next, a second embodiment of the present disclosure will be described with reference to FIG. 7 and FIG. 8 as appropriate. In a substrate processing apparatus according to the second embodiment, the same components as those of the first embodiment are denoted by the same reference numerals as those of the first embodiment, and a detailed description thereof will be omitted.

### Second Embodiment

### (Configuration)

As illustrated in FIG. 7, in the substrate processing apparatus according to the present embodiment, the downstream side of the tank 95 is different from that of the first embodiment. More specifically, in the substrate processing apparatus according to the present embodiment, the tank 95 and the processing chamber 2 are connected in parallel by the first flow path 96A, the second flow path 96B, and a third flow path 96C. In the following description, when the first flow path 96A, the second flow path 96B, and the third flow path 96C are not distinguished, one, two, or three thereof are referred to as a gas flow path 96. The gas flow path 96 as a gas control mechanism is provided with a first flow rate adjustment valve 97A, a second flow rate adjustment valve 97B, and a third flow rate adjustment valve 97C. Specifically, the first flow rate adjustment valve 97A is provided in the first flow path 96A, the second flow rate adjustment valve 97B is provided in the second flow path 96B, and the third flow rate adjustment valve 97C is provided in the third flow path 96C. Here, the third flow rate adjustment valve 97C is an example of a third valve in the present disclosure.

The third flow rate adjustment valve 97C is connected to the I/O port 41d of the substrate processing apparatus similarly to the other valves, and is controlled by the CPU 41b.

Other components are the same as those of the first embodiment.

### <Method of Manufacturing Semiconductor Device and Method of Processing Substrate>

Next, an example of a method of manufacturing a semiconductor device and a method of processing a substrate will be described with reference to FIG. 8 and Table 2. Here, film forming processing of alternately supplying a source gas (for example, Si source gas) and a reaction gas (for example, nitrogen-containing gas) to the processing chamber to form a film (for example, SiN film) on the substrate will be described. In the method of manufacturing a semiconductor device and the method of processing a substrate according to the second embodiment, the same reference numerals as those in the first embodiment are used for the same components and processing as those in the first embodiment, and detailed description thereof will be omitted. In the present embodiment, processes other than the film forming process 1 can be performed in the same manner as in the first embodiment. Hereinafter, details of the film forming process 1 will be described using FIG. 8 and Table 2.

Table 2 shows opening and closing of the first valve (first flow rate adjustment valve 97A), the second valve (second flow rate adjustment valve 97B), and the third valve (third flow rate adjustment valve 97C) and change in the conductance of gas in the gas flow path 96 in a source gas supply process of the present embodiment.

TABLE 2

| Processing | (a2) | . . . | (b1) | . . . | (b2) | . . . | (b3) | . . . | (a3) |
|---|---|---|---|---|---|---|---|---|---|
| First valve | Open | Open | Close | Close | Open | Open | Open | Open | Close |
| Second valve | Open | Open | Open | Open | Open | Open | Open | Open | Close |
| Third valve | Close | Close | Close | Close | Close | Close | Open | Open | Close |
| Conductance CV | A + B | A + B | B | B | A + B | A + B | A + B + | A + B + | 0 |
| | | | | | | | C | C | |

Regarding the conductance in Table 2, “A” indicates the conductance of the first flow rate adjustment valve 97A, “B” indicates the conductance of the second flow rate adjustment valve 97B, and “C” indicates the conductance of the third flow rate adjustment valve 97C. Here, the value A, the value B, and the value C satisfy A>C>B.

### (Film Forming Process 1)

First, as in the first embodiment, the controller 41 performs (a1) processing of storing the source gas in the tank 95.

Subsequently, the controller 41 supplies the source gas in the tank 95 to the processing chamber 2 via the first flow path 96A and the second flow path 96B by opening both the first flow rate adjustment valve 97A and the second flow rate adjustment valve 97B. That is, the controller 41 executes the processing of (a2) in the present disclosure.

Subsequently, the controller 41 executes processing of waiting for a first time that is a predetermined time. For example, the controller 41 waits in a range of 0.05 seconds to 2.00 seconds.

Subsequently, the controller 41 executes processing of closing the first flow rate adjustment valve 97A. At this time, since the source gas inside the tank 95 is supplied to the processing chamber 2 through the second flow path 96B, the conductance in the gas flow path 96 decreases as compared with that after the processing of (a2). That is, the controller 41 executes (b1) processing of decreasing the conductance in the gas flow path 96 in the present disclosure. In other words, the controller 41 decreases the conductance of the gas flow path 96. Here, the processing of (b1) is an example of the processing of (b) in the present disclosure.

Subsequently, the controller 41 executes processing of waiting for a second time that is a predetermined time. For example, the controller 41 waits in a range of 0.05 seconds to 2.00 seconds.

Subsequently, the controller 41 executes processing of opening first flow rate adjustment valve 97A. At this time, since the source gas in the tank 95 is supplied to the processing chamber 2 through the first flow path 96A and the second flow path 96B, the conductance in the gas flow path 96 is increased as compared with that after the processing of (b1). That is, the controller 41 executes (b2) processing of increasing the conductance in the gas flow path 96 in the present disclosure. In other words, the controller 41 decreases the conductance of the gas flow path 96. Here, the processing of (b2) is an example of the processing of (b) in the present disclosure.

Subsequently, the controller 41 executes processing of waiting for a third time that is a predetermined time. For example, the controller 41 waits in a range of 0.05 seconds to 2.00 seconds.

Subsequently, the controller 41 executes processing of opening the third flow rate adjustment valve 97C. At this time, since the source gas in the tank 95 is supplied to the processing chamber 2 through the first flow path 96A, the second flow path 96B, and the third flow path 96C, the conductance in the gas flow path 96 increases as compared with that after the processing of (b2). That is, the controller 41 executes (b3) processing of increasing the conductance in the gas flow path 96 in the present disclosure. In other words, the controller 41 increases the conductance of the gas flow path 96. At this time, as shown in FIG. 8, it is preferable to perform the processing of (b3) such that the pressure of the source gas, the flow rate of the source gas, and the flow velocity of the source gas in the processing chamber 2 increase. Here, the processing of (b3) is an example of the processing of (b) in the present disclosure.

Subsequently, the controller 41 executes processing of waiting for a predetermined time. For example, the controller 41 waits in a range of 0.05 seconds to 2.00 seconds. The third time is preferably set such that a predetermined parameter is equal to or greater than a target value between the processing of (b2) and the processing of (b3). Here, the predetermined parameter is, for example, at least one or more of the flow velocity of the process gas supplied to the substrate, the pressure of the gas in the processing chamber 2, and the flow rate of the process gas supplied to the processing chamber 2 per unit time.

Subsequently, the controller 41 executes processing of closing the first flow rate adjustment valve 97A, the second flow rate adjustment valve 97B, and the third flow rate adjustment valve 97C. That is, the controller 41 executes (a3) processing of stopping the supply of the process gas in the storage into the processing chamber 2 in the present disclosure.

Next, operations and effects of the present embodiment will be described.

### (Operations and Effects)

Also in the present embodiment, effects similar to those of the above-described aspect can be obtained. Furthermore, in the present embodiment, one or more effects described below can be further obtained.

(1) In the present embodiment, the first flow path 96A, the second flow path 96B, and the third flow path 96C are provided as the gas flow path 96 between the plurality of gas flow paths connecting the tank 95 and the processing chamber 2 in parallel, and the first flow rate adjustment valve 97A, the second flow rate adjustment valve 97B, and the third flow rate adjustment valve 97C are disposed therein as the gas control mechanism, and the processing of (b) is performed by controlling these valves. This makes it easier to control the conductance of the entire gas flow path 96 as compared with a case in which there are two parallel flow paths. Specifically, since the maximum conductance amount in the entire gas flow path 96 can be made larger than that in the first embodiment, the step coverage can be further improved.

(2) In the present embodiment, in the processing of (b), (b3) processing of increasing the conductance is further performed after the processing of (b1) and the processing of (b2) in the first embodiment. Accordingly, in the present embodiment, the step coverage can be further improved as compared with the first embodiment.

(3) In the present embodiment, the processing of (b3) is started after the third time has elapsed from the start of (b2), and the third time is set such that a predetermined parameter becomes equal to or greater than a target value between the processing of (b1) and the processing of (b2). Here, the predetermined parameter is at least one of the flow velocity of the process gas, the pressure in the processing chamber 2, and the supply flow rate of the process gas. By setting the third time and the target value of the predetermined parameter in accordance with processing conditions for the substrate, it is possible to suppress that the process gas is not supplied under sufficient conditions for improving the step coverage, and an excessive amount of process gas is supplied for the effect of improving the step coverage.

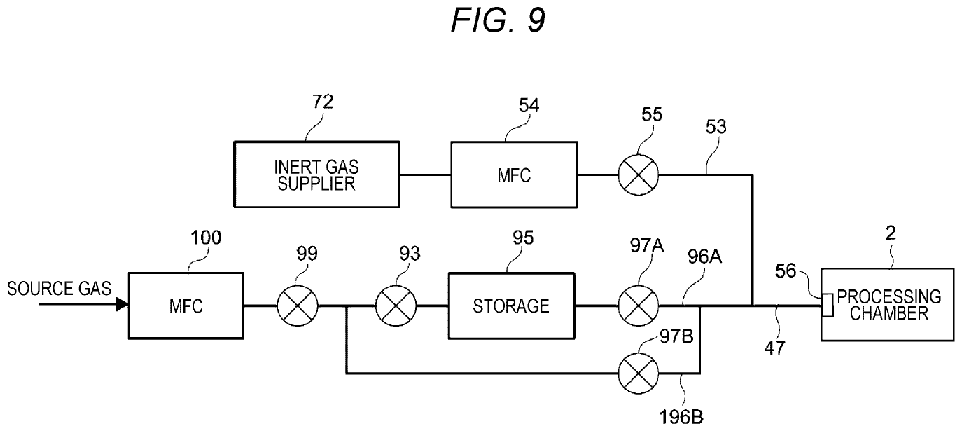

Next, a third embodiment of the present disclosure will be described with reference to FIG. 9 as appropriate. In a substrate processing apparatus according to the third embodiment, the same components as those of the first embodiment or the second embodiment are denoted by the same reference numerals as those of the first embodiment or the second embodiment, and detailed description thereof will be omitted.

### Third Embodiment

### (Configuration)

As illustrated in FIG. 9, in the substrate processing apparatus according to the present embodiment, a supply amount adjustment valve 99, a storage amount adjustment valve 93, a tank 95, a first flow rate adjustment valve 97A, and a first nozzle 56 are provided on the downstream side of an MFC 100 of a first gas supply pipe 47 in order from the upstream. The supply amount adjustment valve 99 and the storage amount adjustment valve 93, and the first flow rate adjustment valve 97A and the first nozzle 56 are connected by a gas flow path 196B, and a second flow rate adjustment valve 97B is provided in the gas flow path 196B.

Here, in the substrate processing apparatus according to the present embodiment, when the first flow rate adjustment valve 97A is opened in a state in which the storage amount adjustment valve 93 and/or the second flow rate adjustment valve 97B are closed, the process gas in the tank 95 flows through a flow path (first flow path) of the gas sequentially passing through the first flow rate adjustment valve 97A and the first nozzle 56, and is supplied into the processing chamber 2. When the storage amount adjustment valve 93 and the second flow rate adjustment valve 97B are opened in a state in which the first flow rate adjustment valve 97A and the supply amount adjustment valve 99 are closed, the process gas in the tank 95 flows through a flow path (second flow path) of the gas sequentially passing through the storage amount adjustment valve 93, the second flow rate adjustment valve 97B, and the first nozzle 56, and is supplied into the processing chamber 2. That is, the first flow path and the second flow path in the present embodiment connect the tank 95 and the processing chamber 2 in parallel. Hereinafter, in the present embodiment

Other components are the same as those of the substrate processing apparatus according to the first embodiment.

### <Method of Manufacturing Semiconductor Device and Method of Processing Substrate>

Next, an example of a method of manufacturing a semiconductor device and a method of processing a substrate will be described. Here, a film forming process of alternately supplying a source gas and a reaction gas to the processing chamber to form a film on the substrate will be described. In the method of manufacturing a semiconductor device and the method of processing a substrate according to the third embodiment, the same reference numerals as those in the first embodiment are used for the same configurations and processes as those in the first embodiment, and detailed description thereof will be omitted. In the present embodiment, processes other than the film forming process 1 can be performed in the same manner as in the first embodiment. Hereinafter, details of the film forming process 1 in the present embodiment will be described.

### (Film Forming Process 1)

The controller 41 opens the supply amount adjustment valve 99 and the storage amount adjustment valve 93 and closes the second flow rate adjustment valve 97B. Then, the controller 41 executes processing of supplying the source gas vaporized by the vaporizer 91 to the tank 95 via the first MFC 100 and storing the source gas in the tank 95. That is, the controller 41 executes (a1) processing of storing the process gas in the storage. The controller 41 closes the supply amount adjustment valve 99 and the storage amount adjustment valve 93 after a predetermined amount of source gas is stored in the tank 95.

Subsequently, the controller 41 opens the storage amount adjustment valve 93, the first flow rate adjustment valve 97A, and the second flow rate adjustment valve 97B. As a result, the source gas in the tank 95 is supplied to the processing chamber 2 through the first flow path and the second flow path. That is, the controller 41 executes processing of (a2).

Subsequently, the controller 41 executes processing of waiting for a first time that is a predetermined time.

Subsequently, the controller 41 closes the first flow rate adjustment valve 97A while keeping the storage amount adjustment valve 93 and the second flow rate adjustment valve 97B open. In this case, the source gas in the tank 95 is supplied to the processing chamber 2 through the second flow path. Following the processing of (a2), the storage amount adjustment valve 93 and the second flow rate adjustment valve 97B may be closed while the first flow rate adjustment valve 97A is opened. In this case, the source gas in the tank 95 is supplied to the processing chamber 2 through the first flow path. In either case, the conductance of the gas flow path 96 decreases as compared with that after the processing of (a2). That is, as in the first embodiment, (b1) processing of decreasing the conductance in the gas flow path 96 is executed.

Subsequently, the controller 41 executes processing of waiting for a second time that is a predetermined time.

Subsequently, the controller 41 opens the first flow rate adjustment valve 97A while keeping the storage amount adjustment valve 93 and the second flow rate adjustment valve 97B open. As a result, the source gas in the tank 95 is supplied to the processing chamber 2 through the first flow path and the second flow path. At this time, the conductance of the gas flow path 96 increases as compared with that after the processing of (b1). That is, as in the first embodiment, (b2) processing of increasing the conductance in the gas flow path 96 is executed.

Subsequently, the controller 41 executes processing of waiting for a predetermined time.

Subsequently, the controller 41 executes processing of closing the first flow rate adjustment valve 97A and the second flow rate adjustment valve 97B. That is, the controller 41 executes (a3) processing of stopping the supply of the process gas in the storage into the processing chamber 2. In other words, the controller 41 decreases the conductance of the gas flow path 96.

As described above, also in the substrate processing apparatus according to the present embodiment, the processing of (b1) and the processing of (b2) as the processing of (b) can be performed as in the first embodiment. Also in the substrate processing apparatus according to the present embodiment, the same operations and effects as those of the first embodiment can be obtained.

### Other Embodiments

Although the embodiments of the present disclosure have been specifically described above, the present disclosure is not limited to the above-described embodiments, and various modifications can be made without departing from the scope of the present disclosure.

For example, in the above description, each of the flow rate adjustment valves 97 is an on-off valve, but the gas control mechanism according to the present disclosure is not limited thereto. For example, one or more of the plurality of flow rate adjustment valves 97 may be opening adjustment valves capable of adjusting opening, and all the flow rate adjustment valves 97 may be opening adjustment valves. Even in such a case, effects similar to the effects described above can be obtained. However, when all the flow rate adjustment valves 97 are flow rate adjustment valves, it is preferable to control the conductance in the gas flow path 96 by opening and closing the flow rate adjustment valve 97 having the largest maximum conductance in the processing of (b).

Further, for example, a case in which one vaporizer 91 and one mass flow controller (first MFC 100) are provided in the substrate processing apparatus has been exemplified in the present embodiment, but the present disclosure is not limited thereto. Although not illustrated, a plurality of vaporizers and a plurality of mass flow controllers may be disposed in parallel.

As the nitrogen-containing gas, one or more of a nitrous oxide (N₂O) gas, a nitrogen monoxide (NO) gas, a nitrogen dioxide (NO₂) gas, an ammonia (NH₃) gas, and the like can be used.

In addition, a reactant is not limited to a nitrogen-containing gas, and another type of thin film may be formed using a gas that reacts with a source to perform film processing. Furthermore, film forming processing may be performed using three or more kinds of process gases.

In addition, for example, in each of the above-described embodiments, film forming processing in a semiconductor device is taken as an example of processing performed by the substrate processing apparatus, but the present disclosure is not limited thereto. The technology of the present disclosure can be applied to all processing performed by exposing a workpiece on which a pattern having a high aspect ratio (that is, a depth larger than a width) is formed to a vaporized gas. That is, in addition to the film forming processing, processing of forming an oxide film and a nitride film, and processing of forming a film containing metal may be used. In addition, the specific content of substrate processing is irrelevant, and the present disclosure can be suitably applied not only to film forming processing but also to other substrate processing such as oxidation processing, nitriding processing, and a dry etching processing. Further, the present disclosure can also be suitably applied to substrate processing using plasma.

Furthermore, the present disclosure can be suitably applied to other substrate processing apparatuses, for example, other substrate processing apparatuses such as an oxidation processing apparatus, a nitriding processing apparatus, a dry etching processing apparatus, and a processing apparatus using plasma. In the present disclosure, these apparatuses may be mixed.

Further, the method of manufacturing a semiconductor device and the method of processing a substrate have been described in the present embodiment, but the present disclosure is not limited thereto. For example, the present disclosure can also be applied to substrate processing such as a liquid crystal device manufacturing process, a solar cell manufacturing process, a light emitting device manufacturing process, a glass substrate processing process, a ceramic substrate processing process, and a conductive substrate processing process.

Further, a part of the configuration of a certain embodiment can be replaced with the configuration of another embodiment, and the configuration of another embodiment can be added to the configuration of a certain embodiment. In addition, it is also possible to add, delete, and replace other configurations for a part of the configuration of each embodiment.

In addition, in the above-described embodiments, an example in which N₂ gas is used as an inert gas has been described, but the present disclosure is not limited thereto, and a rare gas such as an Ar gas, a He gas, a Ne gas, or a Xe gas may be used. However, in this case, it is necessary to prepare a rare gas source. In addition, it is necessary to connect this rare gas source to the first gas supply pipe 47 such that the rare gas can be introduced.

It is preferable to individually prepare (prepare a plurality of) process recipes (programs in which processing procedures, processing conditions, and the like are described) used for forming these various thin films according to the contents of substrate processing (film type, composition ratio, film quality, film thickness, processing procedure, processing conditions, and the like of a thin film to be formed). When substrate processing is started, it is preferable to appropriately select an appropriate process recipe from among a plurality of process recipes according to the content of substrate processing. Specifically, it is preferable that a plurality of process recipes individually prepared according to the contents of substrate processing be stored (installed) in advance in the memory 41c included in the substrate processing apparatus via a telecommunication line or a recording medium (external memory 412) in which the process recipes are recorded. When substrate processing is started, it is preferable that the CPU 41a included in the substrate processing apparatus appropriately select an appropriate process recipe from among a plurality of process recipes stored in the memory 41c according to the content of substrate processing. With such a configuration, thin films of various film types, composition ratios, film qualities, and film thicknesses can be generally formed with high reproducibility by one substrate processing apparatus. In addition, it is possible to reduce an operation load (a processing procedure, an input load of processing conditions, and the like) of an operator, and it is possible to rapidly start substrate processing while avoiding an operation error.

In the above-described embodiments, an example of film formation using a substrate processing apparatus that processes a plurality of substrates at a time has been described. However, the present disclosure is not limited thereto. The present disclosure can also be suitably applied to a case in which a film is formed using a substrate processing apparatus that processes one substrate at a time. Even in the case of using such a substrate processing apparatus, film formation can be performed under the same sequence and processing conditions as in the above-described embodiments. In addition, in the above-described embodiments, an example of forming a film using a hot-wall-type substrate processing apparatus has been described. The present disclosure is not limited to the above-described embodiments, and can be suitably applied to a case in which a film is formed using a cold-wall-type substrate processing apparatus.

According to the present disclosure, it is possible to process a groove having a high aspect ratio with good step coverage.

What is claimed is:

1. A substrate processing apparatus comprising:
a storage configured to store a process gas supplied from a supplier;
a processing chamber configured to process a substrate;
a plurality of gas flow paths that connect the storage and the processing chamber in parallel;
a gas control mechanism including a plurality of valves respectively disposed in the plurality of gas flow paths; and
a controller configured to be capable of controlling the gas control mechanism so as to perform a process including:
(a1) storing the process gas in the storage;
(a2) starting supply of the process gas in the storage into the processing chamber;
(a3) stopping supply of the process gas in the storage into the processing chamber; and
(b) changing conductance of gas in the gas flow paths by controlling opening degrees of the valves between (a2) and (a3).

2. The substrate processing apparatus according to claim 1, wherein
a first flow path and a second flow path are included as the plurality of gas flow paths, and
the gas control mechanism includes, as the plurality of valves, a first valve disposed in the first flow path and a second valve disposed in the second flow path.

3. The substrate processing apparatus according to claim 1, wherein
a first flow path, a second flow path, and a third flow path are included as the plurality of gas flow paths, and
the gas control mechanism includes, as the plurality of valves, a first valve disposed in the first flow path, a second valve disposed in the second flow path, and a third valve disposed in the third flow path.

4. The substrate processing apparatus according to claim 1, wherein
at least one of the plurality of valves is an on-off valve, and
the controller is further configured to be capable of controlling the gas control mechanism so that the conductance is changed by processing including at least one of opening and closing of one or more of the on-off valves in (b).

5. The substrate processing apparatus according to claim 1, wherein the controller is further configured to be capable of controlling the gas control mechanism so that
(b1) decreasing the conductance is performed in (b).

6. The substrate processing apparatus according to claim 5, wherein the controller is further configured to be capable of controlling the gas control mechanism so that
(b1) is started after a first time has elapsed from (a2),
the first time is set such that a predetermined parameter is equal to or greater than a target value between (a2) and (b1), and
the predetermined parameter is at least one of a flow velocity of the process gas supplied to the substrate, a pressure in the processing chamber, or a flow rate of the process gas supplied to the processing chamber per unit time.

7. The substrate processing apparatus according to claim 1, wherein the controller is further configured to be capable of controlling the gas control mechanism so that
(b2) increasing the conductance is performed in (b).

8. The substrate processing apparatus according to claim 1, wherein the controller is further configured to be capable of controlling the gas control mechanism so that (b1) decreasing the conductance, and
(b2) increasing the conductance
are performed in (b).

9. The substrate processing apparatus according to claim 8, wherein the controller is further configured to be capable of controlling the gas control mechanism so that (b2) is performed after (b1).

10. The substrate processing apparatus according to claim 9, wherein the controller is further configured to be capable of controlling the gas control mechanism so that
(b1) is started after a first time has elapsed from (a2),
the first time is set such that a predetermined parameter is equal to or greater than a target value between (a2) and (b1), and
the predetermined parameter is at least one of a flow velocity of the process gas supplied to the substrate, a pressure in the processing chamber, or a flow rate of the process gas supplied to the processing chamber per unit time.

11. The substrate processing apparatus according to claim 9, wherein the controller is further configured to be capable of controlling the gas control mechanism so that
(b2) is started after a second time has elapsed from (b1),
the second time is set such that a predetermined parameter is equal to or greater than a target value between (b1) and (b2), and
the predetermined parameter is at least one of a flow velocity of the process gas supplied to the substrate, a pressure in the processing chamber, and or a flow rate of the process gas supplied to the processing chamber per unit time.

12. The substrate processing apparatus according to claim 9, wherein the controller is further configured to be capable of controlling the gas control mechanism so that
in (b), after (b2), (b3) increasing the conductance is further performed.

13. The substrate processing apparatus according to claim 12, wherein the controller is further configured to be capable of controlling the gas control mechanism so that
(b3) is started after a third time has elapsed from (b2),
the third time is set such that a predetermined parameter is equal to or greater than a target value between (b2) and (b3), and
the predetermined parameter is at least one of a flow velocity of the process gas supplied to the substrate, a pressure in the processing chamber, or a flow rate of the process gas supplied to the processing chamber per unit time.

14. The substrate processing apparatus according to claim 1, wherein
the processing chamber is configured to be capable of processing a plurality of substrates.

15. The substrate processing apparatus according to claim 4, wherein the controller is further configured to be capable of controlling the gas control mechanism so that
in (b), the conductance is changed by processing including opening and closing of an on-off valve having a largest maximum conductance among the plurality of valves.

16. A substrate processing method by using a substrate processing apparatus comprising:
a storage configured to store a process gas supplied from a supplier;
a processing chamber configured to process a substrate;
a plurality of gas flow paths that connect the storage and the processing chamber in parallel;
a gas control mechanism including a plurality of valves respectively disposed in the plurality of gas flow paths; and
a controller configured to be capable of controlling the gas control mechanism, wherein the substrate processing method comprising:
(a1) storing the process gas in the storage;
(a2) starting supply of the process gas in the storage into the processing chamber;
(a3) stopping supply of the process gas in the storage into the processing chamber; and
(b) changing conductance of gas in the gas flow paths by controlling opening degrees of the valves between (a2) and (a3).

17. A method of manufacturing a semiconductor device comprising the method of claim 16.

18. A computer-readable recording medium recording a program for causing a substrate processing apparatus to execute, by a computer, a procedure,
wherein the substrate processing apparatus comprising:
a storage configured to store a process gas supplied from a supplier;
a processing chamber configured to process a substrate;
a plurality of gas flow paths that connect the storage and the processing chamber in parallel;
a gas control mechanism including a plurality of valves respectively disposed in the plurality of gas flow paths; and
a controller configured to be capable of controlling the gas control mechanism, and
wherein the procedure comprising:
(a1) storing the process gas in the storage;
(a2) starting supply of the process gas in the storage into the processing chamber;
(a3) stopping supply of the process gas in the storage into the processing chamber, and
(b) changing conductance of gas in the gas flow paths by controlling opening degrees of the valves between (a2) and (a3).
